(19) United States
(12) Patent Application Publication
(10) Pub. No.: US 2004/0187910 A1
(43) Pub. Date: Sep. 30, 2004

(54) Photovoltaic cell

(76) Inventor: William Clark II, Moses Lake, WA (US)

Correspondence Address: Douglas E. McKinley, Jr., McKinley Law Office, P.O. Box 202, Richland, WA, 99352, US

(21) Appl. No.: 10/396,803

(22) Filed: Mar. 24, 2003

(51) Int. Cl. H01L 31/00

(52) U.S. Cl. 136/252; 136/293; 136/243

(57) ABSTRACT

A photovoltaic cell utilizing antenna capable of receiving electromagnetic energy from a solar source, connected to and configured as the AC input of, a rectifier or an array of antennas, each capable of inductively coupling with, and thereby receiving electromagnetic energy from, a solar source connected to, and configured as the AC input of, a plurality of rectifiers. The antennas and plurality of rectifiers are preferably provided as an integrated circuit formed on a substrate by standard photolithographic etching techniques utilized in the semiconductor industry.

### CROSS-REFERENCE TO RELATED APPLICATIONS

Not Applicable

### BACKGROUND OF THE INVENTION

Edmond Becquerel first described the photovoltaic (PV) effect in 1839, when the 19 year old French physicist found that certain materials would produce small amounts of electric current when exposed to light. The effect was further studied in solids, such as selenium, by Heinrich Hertz in the 1870s. Soon afterward, selenium PV cells were converting light to electricity at 1% to 2% efficiency. As a result, selenium was quickly adopted in the emerging field of photography for use in light-measuring devices.

Major steps toward commercializing PV were taken in the 1940s and early 1950s, when the Czochralski process was developed for producing highly pure crystalline silicon. In 1954, scientists at Bell Laboratories used on the Czochralski process to develop the first crystalline silicon photovoltaic cell, which had an efficiency of 4%. In 1954, the PV effect in Cd was reported; primary work was performed by Rappaport, Loferski and Jenny at RCA. Bell Labs researchers Pearson, Chapin, and Fuller reported their discovery of 4.5% efficient silicon solar cells; this was raised to 6% only a few months later by a work team including Mort Prince. In 1957, Hoffman Electronics achieved 8% efficient cells and U.S. Pat. No. 2,780,765, “Solar Energy Converting Apparatus,” was issued to Chapin, Fuller, and Pearson of AT&T. By 1960, Hoffman electronics had reported 14% efficient PV cells.

Today, silicon is the most popular PV cell material for commercial applications because it is so readily abundant. However, to be useful in solar cells, it must be refined to 99.9999% purity. In single-crystal silicon, the molecular structure of the material is uniform because the entire structure is grown from the same or a “single” crystal. This uniformity is ideal for efficiently transferring electrons through the material. To make an effective PV cell, silicon is “doped” to make it n-type and p-type. Semicrystalline silicon, on the other hand, consists of several smaller crystals or “grains,” which introduce “boundaries.” These boundaries impede the flow of electrons and encourage them to recombine with holes and thereby reduce the power output of the cell. However, semicrystalline silicon is much cheaper to produce than single-crystalline silicon, so significant research continues seeking ways of minimizing the effects of grain boundaries.

Gallium arsenide (GaAs) has also found use for the production of PVs. GaAs is a compound semiconductor: a mixture of two elements, gallium (Ga) and arsenic (As). Gallium is a byproduct of the smelting of other metals, notably aluminum and zinc. Gallium arsenide's use in solar cells has been developing synergistically with its use in light-emitting diodes, lasers, and other opto-electronic devices.

GaAs is especially suitable for use in multijunction and high-efficiency solar cells for several reasons. The GaAs band gap is 1.43 eV, nearly ideal for single-junction solar cells. GaAs has an absorbtivity so high it requires a cell only a few microns thick to absorb sunlight. (Crystalline silicon requires a layer 100 microns or more in thickness.) Unlike silicon cells, GaAs cells are relatively insensitive to heat. (Cell temperatures can often be quite high, especially in concentrator applications.) Alloys made from GaAs using aluminum, phosphorus, antimony, or indium have characteristics complementary to those of gallium arsenide, allowing great flexibility in cell design. GaAs is very resistant to radiation damage. This, along with its high efficiency, makes GaAs very desirable for space applications.

One of the greatest advantages of gallium arsenide and its alloys as PV cell materials is the wide range of design options possible. A cell with a GaAs base can have several layers of slightly different compositions that allow a cell designer to precisely control the generation and collection of electrons and holes. (To accomplish the same thing, silicon cells have been limited to variations in the level of doping.) This degree of control allows cell designers to push efficiencies closer and closer to theoretical levels. For example, one of the most common GaAs cell structures uses a very thin window layer of aluminum gallium arsenide. This thin layer allows electrons and holes to be created close to the electric field at the junction.

One of the scientific discoveries of the computer semiconductor industry that has shown great potential for the PV industry is thin film technology. Polycrystalline thin film devices require very little semiconductor material and have the added advantage of being easy to manufacture. Rather than growing, slicing, and treating a crystalline ingot (required for single-crystal silicon), we sequentially deposit thin layers of the required materials. Several different deposition techniques are available, and all of them are potentially cheaper than the ingot growth techniques required for crystalline silicon. Best of all, these deposition processes can be scaled uneasily so that the same technique used to make a 2-inch×2-inch laboratory cell can be used to make a 2-foot×5-foot module (in a sense, a huge cell!). Like amorphous silicon, the layers can be deposited on various low-cost substrates (actually “superstrates,” see Transparent Conductors) like glass or plastic in virtually any shape—even flexible plastic sheets.

Single-crystal cells have to be individually interconnected into a module, but thin film devices can be made monolithically (as a single unit). Layer upon layer is deposited sequentially on a glass superstrate, from the antireflection coating and conducting oxide, to the semiconductor materialand the back electrical contacts.

Unlike most single-crystal cells, the typical thin film device does not use a metal grid for the top electrical contact. Instead, it uses a thin layer of a transparent conducting oxide (such as tin oxide). These oxides are highly transparent and conduct electricity very well. A separate antireflection coating may be used to top off the device, or the transparent conducting oxide may serve this function as well.

Polycrystalline thin film cells comprise many tiny crystalline grains of semiconductor materials. The materials used in polycrystalline thin-film cells have properties that are different from those of silicon, so it has proven to be better to create the electric field with an interface between two different semiconductor materials. This type of interface is called a heterojunction (“hetero” because it is formed from two different materials, in comparison to the “homojunction” formed by two doped layers of the same material, such as the one in silicon solar cells).

As a result of these and other developments, photovoltaic or solar cells have gained wide recognition as an effective and environmentally acceptable method for generating electrical energy. However, despite the use of various materials and designs, the steady improvements in PV cell efficiency appear to have reached a plateau. Commercially available PV devices typically achieve between 7 and 17% conversion efficiencies, not much better than those reported as late as 1960.

One potential reason for the plateau in efficiency may be related to the fact that PV cells rely on the “particle” nature of light to generate electricity. In these cells, a layer of a “p” type material, such as silicon crystals doped with boron, is joined with a layer of an “n” type material, such as silicon crystals doped with phosphorus, to form a PV cell having an electrical field. This establishes a voltage difference between the two sides of the wafer. In silicon this is just under half a volt. Metallic contacts are made to both sides of the wafer. When the wafer is bombarded by the photons in sunlight, photons are absorbed in the “p” type layer and electrons are knocked off the silicon atoms and are drawn to one side of the wafer by the voltage difference. If an external circuit is attached to the contacts, the electrons have a way to get back to where they came from and a current flows through the circuit. The PV cell acts like an electron pump. The amount of current is determined by the number of electrons that the solar photons knock off the silicon atoms, so by the size of the cell, the amount of light on the cell and the efficiency of the cell.

Accordingly, there exists a need for photovoltaic cells that have higher levels of efficiency than those currently available.

### BRIEF SUMMARY OF THE INVENTION

It is therefore an object of the present invention to provide a photovoltaic cell capable of achieving efficiencies of greater than the efficiencies of current PV devices. It is a further object of the present invention a photovoltaic cell capable of achieving greater efficiencies that can be mass produced using existing technologies and processes. It is a further object of the present invention a photovoltaic cell capable of achieving greater efficiencies that can be readily configured to provide any desired voltage. It is a further object of the present invention a photovoltaic cell capable of achieving greater efficiencies of that has high levels of internal current.

These and other objects are accomplished by providing a photovoltaic cell that is designed to utilize solar energy's wave properties, as opposed to traditional photovoltaic cells, which are designed solely to utilize solar energy's particle properties. It should be noted that the present invention can readily be manufactured utilizing materials that take advantage of solar energy's particle properties, thereby generating electrical power in a manner identical to currently available photovoltaic devices in addition to the method of the present invention, and such combinations and modifications are expressly within the contemplation of the present invention. However, the basis for the enhanced efficiency of the present invention is the exploitation of solar energy's wave properties.

Accordingly, the present invention is a photovoltaic cell capable of converting light into electrical power. The photovoltaic cell of the present invention utilizes an antenna capable of receiving electromagnetic energy from a solar source, connected to and configured as the AC input of, a rectifier. More specifically, the photovoltaic cell of the present invention preferably utilizes an array of antennas, each capable of inductively coupling with, and thereby receiving electromagnetic energy from, a solar source. The antennas are then connected to, and configured as the AC input of, a plurality of rectifiers. The antennas and plurality of rectifiers are preferably provided as an integrated circuit formed on a substrate by standard photolithographic etching techniques utilized in the semiconductor industry. In this manner, the antennas may readily be manufactured at a scale suitable for inductively coupling with electromagnetic energy from the sun.

For example, and not meant to be limiting, visible light emitted by the sun is generally of a wavelength of about 5×10⁻⁷ meters, equaling about 2.5 electron volts. Standard semiconductor manufacturing techniques readily allow for the manufacture of an array of antennas at full, half, and one quarter this wavelength. Further, standard semiconductor manufacturing techniques readily allow for the manufacture of microscale diodes which are in turn configured as rectifiers, and attached to these antennas. As contemplated by the present invention, an array of such antennas and rectifiers may thus be manufactured as connected in series, in parallel, or in a combination of series and parallel.

Each individual rectifier/antenna pair when inductively coupled with the sun's electromagnetic energy at the visible wavelength produces significant voltage, but limited current. Thus, during operation, each rectifier/antenna pair produces relatively low levels of heat, and thus resistance, when compared to conventional photovoltaic devices. This allows the present invention to operate at higher levels of efficiency than conventional photovoltaic devices. It also allows for the design of a cell, consisting of an array of rectifier/antenna pairs connected in series, in parallel, or in a combination of series and parallel, that is configured and sized to produce a given voltage when exposed to direct sunlight. For example, a cell of rectifier/antenna pairs connected in series, in parallel, or in a combination of series and parallel, that produced approximately 120 volts dc would be highly useful, as the power from such a cell could readily be transformed into ac current and, then regulated and utilized by virtually all known electrical devices commonly plugged into the commercially available power in the United States. Cells producing 220 volts dc would be highly useful in much of Europe and Japan for similar reasons.

As will be recognized by those having skill in the art, a variety of devices and configurations are possible to construct operating rectifiers. All such configurations and devices are expressly included in the definition of “rectifier” herein. The simple four diode rectifiers shown and described below should therefore not be construed as limiting, but rather should be considered as merely examples intended to illustrate the concept of the present invention.

FIG. 1 shows a simple four diode, full wave rectifier 1 which may be usefully employed in the present invention. As shown, an antenna 2 is connected to the top and bottom of the rectifier. When light from the sun inductively couples with the antenna, the diodes 3 rectify the resultant waveforms, providing a dc current through the horizontal connections 4 attached to the diodes. FIG. 2a shows a set of three rectifiers 1 connected in series, and FIG. 2b shows a set of three rectifiers 1 connected in parallel. FIG. 3 shows an array of rectifiers, as they might be usefully arranged in a single cell manufactured using standard semiconductor technology.

### BRIEF DESCRIPTION OF THE SEVERAL VIEWS OF THE DRAWINGS

FIG. 1 shows a simple four diode, full wave rectifier 1 with antennas for gathering solar energy as contemplated by the present invention.

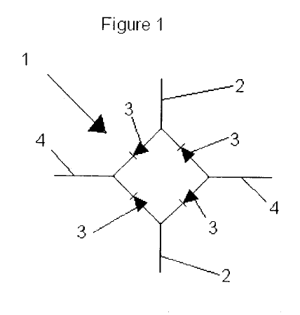

FIG. 2a shows a set of three rectifiers with antennas for gathering solar energy as contemplated by the present invention connected in series, and 2b shows a set of three rectifiers with antennas for gathering solar energy as contemplated by the present invention connected in parallel.

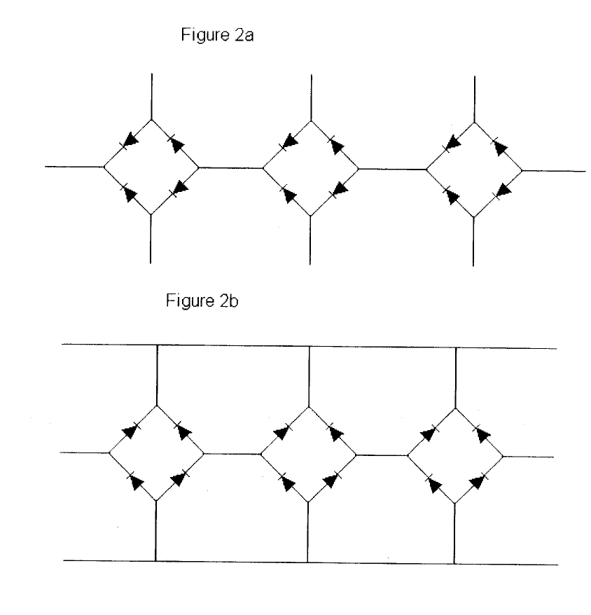

FIG. 3 shows an array of rectifiers with antennas for gathering solar energy as contemplated by the present invention, as they might be usefully arranged in a single cell manufactured using standard semiconductor technology.

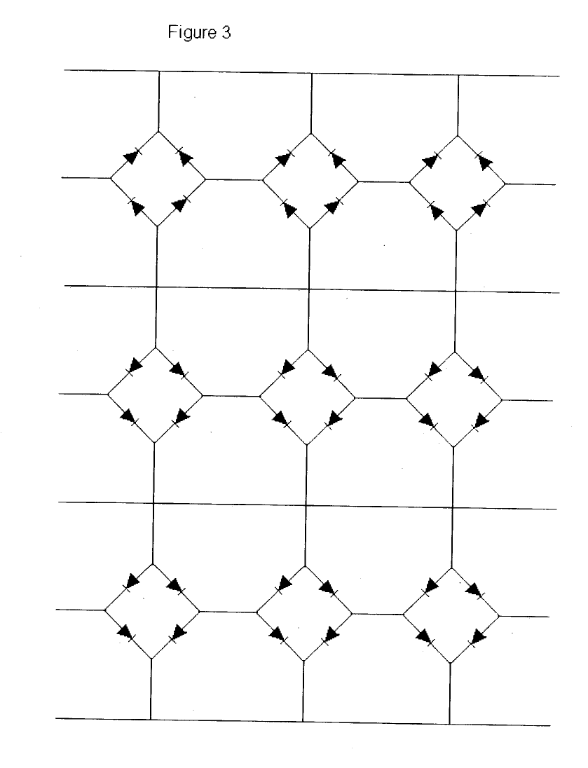

### CLOSURE

While a preferred embodiment of the present invention has been shown and described, it will be apparent to those skilled in the art that many changes and modifications may be made without departing from the invention in its broader aspects. The appended claims are therefore intended to cover all such changes and modifications as fall within the true spirit and scope of the invention.

1) A photovoltaic cell capable of converting light into electrical power comprising:
an antenna capable of receiving electromagnetic energy from a solar source, said antenna connected to and configured as the AC input of a full wave rectifier.

2) A photovoltaic cell capable of converting light into electrical power comprising:
an antenna capable of receiving electromagnetic energy from a solar source, said antenna connected to and configured as the AC input of a plurality of full wave rectifiers.

3) The photovoltaic cell of claim 2 wherein said antenna capable of receiving electromagnetic energy from a solar source and said plurality of full wave rectifiers are provided as an integrated circuit.

4) The photovoltaic cell of claim 2 wherein said antenna capable of receiving electromagnetic energy from a solar source and said plurality of full wave rectifiers are provided as an integrated circuit formed by photolithographic etching on a substrate.

5) The photovoltaic cell of claim 2 wherein at least a portion of said plurality of full wave rectifiers are connected in series.

6) The photovoltaic cell of claim 2 wherein at least a portion of said plurality of full wave rectifiers are connected in parallel.

7) The photovoltaic cell of claim 2 wherein the number of said plurality of full wave rectifiers are selected to provide about 120 volts dc.
